(19) United States
(12) Patent Application Publication
(10) Pub. No.: US 2005/0029646 A1
(43) Pub. Date: Feb. 10, 2005

(54) Semiconductor device and method for dividing substrate

(75) Inventors: Tetsuzo Ueda, Osaka (JP); Daisuke Ueda, Osaka (JP)

Correspondence Address: GREENBLUM & BERNSTEIN, P.L.C., 1950 ROLAND CLARKE PLACE, RESTON, VA, 20191, US

(73) Assignee: Matsushita Electric Industrial Co., Ltd., Osaka (JP)

(21) Appl. No.: 10/912,136

(22) Filed: Aug. 6, 2004

(30) Foreign Application Priority Data
Aug. 7, 2003 (JP) 2003-288751

(51) Int. Cl. G01K 1/08; H01J 3/14; H01L 21/301; H01L 23/22

(52) U.S. Cl. 257/687; 438/460; 438/463; 257/723

(57) ABSTRACT

The object of the present invention is to provide a semiconductor device and a method for dividing a substrate which are capable of preventing chips from breaking and manufacturing chips in a reproducible square-like form. After the surface of the epitaxial growth layer 2 of the end part of the nitride semiconductor wafer is linear-scanned a plurality of times by the electron beam 3 so that scanning lines are parallel, the scribe line 4 is formed. Then, the edge jig 5 is put on the scribe line 4. And, the back surface of the SiC substrate 1 is pressed by the edge jig 6.

### BACKGROUND OF THE INVENTION

(1) Field of the Invention

The present invention relates to a cleavage method and a chip separation method for a semiconductor wafer.

(2) Description of the Related Art

As a GaN type III-V nitride semiconductor (InGaAIN) has a wide band gap width (the band gap width of GaN at room temperature is 3.4 eV), it is a material capable of realizing a high-power light-emitting diode in the wavelength range of the green and blue visible range or the ultraviolet region. A blue and green light-emitting diode and a white light-emitting diode which obtains a white light by exciting a fluorescent substance with a blue or ultraviolet light-emitting diode have been already merchandised. A violet semiconductor laser element which uses such nitride semiconductor as described above has been developed for a next-generation high-density optical disk light source, and it is nearly at the stage of being practically used. Also, a high-frequency and high-power electronic device which utilizes advantages of the nitride semiconductor such as a high saturated drift velocity and a high breakdown voltage has been regarded as promising, and there has been active research and development thereof.

In general, a method of using a thermally stable substrate such as a sapphire substrate and a SiC substrate for a crystal growth of the nitride semiconductor and having a semiconductor layer epitaxially grow on the substrate by the Metal Organic Chemical Vapor Deposition (MOCVD) is used. In addition, a GaN substrate has been easily available recently, and a crystal growth on the substrate has been performed. In both cases such substrates as described above are extremely hard, compared to a Si substrate and a GaAs substrate, and the chip separation of a light-emitting diode or a transistor integrated circuit is difficult. Thus, a method of dicing using, for example, a diamond blade is generally used for the chip separation. However, there are problems such as frequent chip breaking and difficulty of manufacturing chips in a reproducible square-like form. Moreover, in the case of manufacturing a semiconductor laser element, it is necessary to form a resonant mirror by cleavage. However, there is another problem that it is difficult to make the cleaved facet flat. Conventionally, the cleavage has been performed by putting an edge jig on the substrate after forming a linear ditch with, for example, a diamond scriber in, for example, a sapphire substrate or a SiC substrate. Both cases of the above mentioned dicing and cleavage include a process of removing a part where the scribe line is to be formed, said part being of the substrate or the epitaxial layer. And, there are problems that chip breaking is caused and chips cannot be manufactured in a reproducible square-like form. In order to solve such problems as described above, a technology capable of performing a cleavage and a chip separation without causing chip breaking and manufacturing chips in a reproducible square-like form for the nitride semiconductor wafer which is manufactured by forming a nitride semiconductor device on a sapphire substrate or a SiC substrate is needed.

The conventional cleavage method and chip separation method for the nitride semiconductor wafer will be explained as following. Also, an example of such cleavage method as described above is disclosed in, for example, Japanese Laid-Open Patent publication No. H10-70335, 2003-332273.

FIG. 1A is an outside drawing showing the cleavage method for a nitride semiconductor wafer according to the conventional example. And, FIG. 1B is a cross-sectional drawing showing the cleavage method for the nitride semiconductor wafer according to the conventional example.

First, as shown in FIG. 1A, an epitaxial growth layer 2 is formed on a SiC substrate 1 by, for example, the MOCVD method, and an InGaAIN semiconductor laser element is formed. The epitaxial growth layer 2 specifically includes: an n-type InGaAIN cladding layer, an InGaAIN active layer and a p-type InGaAIN cladding layer. The InGaAIN active layer generates a violet laser oscillation at 405 nm. The p-type InGaAIN cladding layer is formed as the surface of the epitaxial growth layer 2, and a patterned p-type ohmic electrode is formed on the p-type InGaAIN cladding layer. Next, after the back surface of the SiC substrate 1 on which the epitaxial growth layer 2 is formed is polished until the thickness of the SiC substrate 1 becomes, for example, 100 μm, an n-type ohmic electrode is formed on the SiC substrate 1. Here, the example of using a SiC substrate is described. In the case of using a sapphire substrate, as the substrate does not have an electrical conductivity, after the p-type InGaAIN cladding layer and the InGaAIN active layer are selectively removed, the n-type ohmic electrode is formed on the surface of the exposed n-type InGaAIN cladding layer. Next, a scribe line 22 heading to the direction of “a” axis (<11-20> direction) which is the cleavage direction of the SiC substrate 1 is formed in the back surface of the SiC substrate 1 with the interval of the resonant length of the semiconductor laser element. A diamond scriber 21 is used for forming the scribe line 22, and the ditch with the depth of about 50 μm is formed.

Next, after forming the scribe line 22, as shown in FIG. 1B, a bar-shaped nitride semiconductor wafer including a plurality of semiconductor laser chips is formed by putting an edge jig 5 on the scribe line 22 of the back surface of the SiC substrate 1 and adding pressure on the epitaxial growth layer 2 with an edge jig 6. Then, semiconductor laser chips can be obtained by repeatedly performing (a) a coating for improving the edge face reflectivity for the cleaved facet 7 of the bar-shaped nitride semiconductor wafer and (b) the above mentioned cleavage process.

FIG. 2 is an outside drawing showing the chip separation method for a nitride semiconductor wafer according to the conventional example.

First, as shown in FIG. 2, an InGaAIN epitaxial growth layer 16 is formed on a SiC substrate 1 by, for example, the MOCVD method. The epitaxial growth layer 16 forms a light-emitting diode or a field-effect transistor integrated circuit. In the case of forming the light-emitting diode, the epitaxial growth layer 16 specifically includes: an n-type InGaAIN layer, an InGaAIN active layer and a p-type InGaAIN layer. The InGaAIN active layer emits a blue light of 470 nm by a current injection. On the other hand, in the case of forming the field-effect transistor, an n-type AlGaN layer is formed on an undoped GaN layer. Next, after the device formation process such as an electrode formation is completed, the SiC substrate 1 is made thin by polishing and the like. After that, as shown in FIG. 2, the chip separation can be performed by cutting the nitride semiconductor wafer with the diamond blade 23 in the “xy” direction.

However, according to the conventional cleavage method and chip separation method for the nitride semiconductor wafer, in both cases of FIG. 1A,1B and FIG. 2, a ditch has to be made in the nitride semiconductor wafer or the nitride semiconductor wafer has to be cut, by using a diamond scriber and the like. And, there are problems such as frequent chip breaking and difficulty of manufacturing chips in a reproducible square-like form. Furthermore, in the case of performing the chip separation, it is necessary to retain the chip width for being cut by the diamond blade. As a result, there is a problem that the total number of chips obtained from one wafer decreases, and the chip cost increases.

### SUMMARY OF THE INVENTION

The first object of the present invention, in view of such technological problems as described above, is to provide a semiconductor device and a method for dividing a substrate which are capable of (a) being applied to a cleavage method and a chip separation method for a nitride semiconductor wafer, (b) preventing chips from breaking and (c) manufacturing chips in a reproducible square-like form.

The second object of the present invention is to provide a semiconductor device and a method for dividing a substrate which are capable of reducing the chip cost.

In order to achieve such objects as described above, the method for dividing a substrate according to the present invention is a method for dividing a substrate in which a semiconductor device is formed. And, the dividing method comprises an electron beam scanning process of generating a crack by scanning a main surface of the substrate with an electron beam.

Thus, in the case of separating a semiconductor wafer as a substrate, the semiconductor wafer is separated with the origin of a crack which is generated by heating and cooling the surface of the semiconductor wafer in a short time with the electron beam irradiation. Thereby, the chip separation which is capable of (a) preventing chips from breaking and (b) manufacturing chips in a reproducible square-like form can be realized. Also, there is no loss of the semiconductor wafer in the scribing part, and many chips can be obtained from one semiconductor wafer. As a result, the chip cost can be reduced.

Here, the method for dividing the substrate may further comprise a metal film formation process of forming, before said electron beam scanning process, a metal film on at least a part of the main surface of the substrate which is scanned by the electron beam. Also, said metal film formation process may form a metal film on a part of the main surface of the substrate, said part being an area where the electron beam passes. Moreover, in said electron beam scanning process the electron beam scanning may be started from an end part of the substrate. And, in said metal film formation process a metal film may be formed on a main surface of an end part of the substrate which is scanned by the electron beam.

Thus, in the electron beam irradiation the substrate is prevented from charging up, and the electron beam can be irradiated in a reproducible straight form. And, in the case of separating a semiconductor wafer as a substrate, the chip separation can be performed in the reproducible square-like form. Also, it is possible to improve the flatness of a divided plane.

In addition, in said electron beam scanning process, the main surface of the substrate may be scanned with the electron beam whose current value is being changed.

Thus, in the case of separating a semiconductor wafer as a substrate, for example, after a crack is generated in the semiconductor wafer by performing a scanning of an electron beam of a high current, the semiconductor wafer can be separated by performing a scanning of an electron beam of a low current. And, the semiconductor wafer can be separated along with the cleaved facet. As a result, it is possible to improve the linearity and the flatness of the semiconductor wafer separation plane.

Also, in said electron beam scanning process, the substrate may be divided in a bar form by performing a linear-scanning of the electron beam a plurality of times so that the scanning lines are parallel.

Thus, in the case of separating a semiconductor wafer as a substrate, it is possible to realize a chip separation capable of manufacturing chips which have accurately flat cleaved facets which can be applied to, for example, a resonant mirror of a semiconductor laser element. Moreover, the cleavage can be performed easily only by the electron beam irradiation. Thereby, the chip cost can be reduced.

The method for dividing the substrate may further comprise: (i) a first coating process of coating, after said electron beam scanning process, an edge face which is exposed by the division of the substrate in the bar form and (ii) a second coating process of coating, after the bar formation process, an edge face which is exposed by the division of the substrate in the bar form.

Thus, in the case of separating a semiconductor wafer as a substrate, a mirror with a high reflectivity can be formed on the cleaved facet. Thereby, it is possible to realize a semiconductor laser element which has a low threshold current.

The method for dividing the substrate may further comprise an insulating film formation process of forming, before said electron beam scanning process, an insulating film on a part of the main surface of the substrate which is scanned by the electron beam, said part being an area where the electron beam does not pass.

Thus, it is possible to irradiate, spotting the insulating film, an electron beam of high position accuracy on the part which is not covered with the insulating film, that is, a part which should be scanned by the electron beam. And, the scanning of accurate linearity can be performed. In the case of separating a semiconductor wafer as a substrate, it is possible to further improve the linearity and flatness of the separation plane.

The insulating film may be a photoresist or a dielectric insulating film. The method for dividing the substrate may further comprise an insulating film removing process of removing the insulating film after said electron beam scanning process.

Thus, in the case of separating a semiconductor wafer as a substrate, it is possible to easily remove the insulating film which is formed on the semiconductor wafer by, for example, an organic solvent, acid and the like after the electron beam irradiation. And, there is no influence of the insulating material. Thereby, it is possible to realize a light-emitting diode and the like with excellent heat radiation.

The semiconductor device may be a semiconductor laser element.

Thus, it is possible to realize a semiconductor laser element which has a low threshold current.

The method for dividing the substrate further comprises an impurities addition process of adding, before said electron beam scanning process, impurities to or forms a film including impurities on a part of the main surface of the substrate which is scanned by the electron beam, said part being an area where the electron beam passes, and in said electron beam scanning process the impurities are diffused by the electron beam scanning.

Thus, the optical band gap width of the part where the electron beam scanning is performed becomes larger than the optical band gap width of the part where the electron beam scanning is not performed. In the case of separating a semiconductor wafer as a substrate, the optical band gap width of the neighbourhood of the separation plane of the chip becomes larger than that of the central part of the chip. And, the light density of the neighborhood of the separation plane, that is, the resonant mirror plane can be decreased. As a result, a high power semiconductor laser element which prevents a catastrophic optical damage can be realized.

Also, the substrate may include a semiconductor layer which is made of InGaAIN.

Thus, it is possible to realize (a) a visible range, an ultraviolet light-emitting diode and a violet semiconductor laser element which have an InGaAIN layer having, for example, a quantum well structure as a light emitting layer and (b) a field effect transistor which has a two-dimensional electron gas in AlGaN/GaN as a channel and an integrated circuit thereof.

The substrate may include a part which is made of SiC, sapphire or GaN.

Thus, it is possible to form an InGaAIN layer having a good crystalline quality on a substrate. And, it is possible to realize (a) a visible range, an ultraviolet InGaAIN light-emitting diode and a violet InGaAIN semiconductor laser element which have a high intensity and (b) an AlGaN/GaN field effect transistor which has a high mobility and an integrated circuit thereof.

Also, the semiconductor device may be a light-emitting diode.

Thus, in the case of separating a semiconductor wafer as a substrate, light-emitting diode chips which have little possibility of being broken and a stable chip form can be realized.

Also, the semiconductor device can be a transistor or an integrated circuit thereof.

Thus, in the case of separating a semiconductor wafer as a substrate, a transistor or an integrated circuit chip thereof which has little possibility of being broken and a stable chip form can be realized.

In addition, in said electron beam scanning process the substrate may be divided in a chip form by performing a linear-scanning of the electron beam a plurality of times so that the scanning lines are crossed.

Thus, in the case of separating a semiconductor wafer as a substrate, the separation can be performed without losing, in the peripheral part, for example, a light-emitting diode, a transistor and the integrated circuit chip thereof. Moreover, it is possible to realize a chip with a low cost by increasing the number of chips in the wafer.

Also, in said electron beam scanning process the main surface may be linear-scanned a plurality of times by the electron beam so that scanning lines are parallel, said main surface being of the end part of the substrate where the metal film is formed, and the method for dividing the substrate further may comprise a bar formation process of forming, after said electron beam scanning process, the substrate in a bar form, dividing the substrate by adding pressure to the main surface of the substrate which has the crack and the main surface of the substrate which does not have the crack.

Thus, in the case of separating a semiconductor wafer as a substrate, it is possible to realize a chip separation capable of manufacturing chips which have accurately flat cleaved facets which can be applied to, for example, a resonant mirror of a semiconductor laser element.

Also, the method for dividing the substrate may further comprise an attachment process of attaching, before the electron beam scanning process, a viscous sheet to the main surface of the substrate which is not scanned by the electron beam, and a pulling process of dividing, after the electron beam scanning process, the substrate by pulling the viscous sheet. And, the viscous sheet may be an electrically conductive viscous sheet.

Thus, in the case of separating a semiconductor wafer as a substrate, it is possible to separate it without discreting the bar-shaped chips or chips. Therefore, the implementation process of performing the implementation of these chips can be simplified.

In addition, the present invention can be utilized for a semiconductor device which comprises a substrate including a thermal degradation layer in the end part.

Thus, in the case where the semiconductor device is a chip, a chip is manufactured of a semiconductor wafer by the separation method which heats and cools the semiconductor wafer in a short time with electron beam irradiation. And, it is possible to realize, for example, a light-emitting diode, a transistor and the integrated circuit chip thereof which are separated without any loss. At the same time, it is possible to realize a chip with low cost which is not lost in the separation part.

Here, the substrate may further include a metal film which is formed on the end part of the substrate.

Thus, in the case where the semiconductor device is a chip, the chip is manufactured of a semiconductor wafer by the separation method which heats and cools the semiconductor wafer in a short time with electron beam irradiation. Thereby, the chip has both high linearity and accurate flatness. And, it is possible to realize, for example, a light-emitting diode, a transistor and the integrated circuit chip thereof.

Also, the semiconductor device can be a semiconductor laser element.

Thereby, a chip where the semiconductor device is formed is manufactured of a semiconductor wafer by the separation method which heats and cools the semiconductor wafer in a short time with electron beam irradiation. Thus, it is possible to realize a semiconductor laser chip which has a stable chip form with little chip loss.

In addition, the thermal degradation layer may have a disordered structure.

Thereby, it is possible to realize a high-power semiconductor laser chip which prevents a catastrophic optical damage.

Also, the substrate may include a semiconductor layer which is made of InGaAIN.

Thus, a chip where the semiconductor device is formed is manufactured of a semiconductor wafer by the separation method which heats and cools the semiconductor wafer in a short time with electron beam irradiation. Thereby, it is possible to realize, for example, (a) a visible range, an ultraviolet light-emitting diode and a violet semiconductor laser element which have a high intensity and an InGaAIN layer having a quantum well structure as a light emitting layer and (b) a field effect transistor which has a two-dimensional electronic gas in AlGaN/GaN as a channel and the integrated circuit thereof.

In addition, the substrate may include a part which is made of SiC, sapphire or GaN.

Thus, it is possible to realize (a) a visible range, an ultraviolet InGaAIN light-emitting diode and a violet InGaAIN semiconductor laser element which have a high intensity, (b) an AlGaN/GaN field effect transistor of a high mobility and the integrated circuit thereof.

Also, the semiconductor device may be a light-emitting diode.

Thus, a chip where the semiconductor device is formed is manufactured of a semiconductor wafer by the separation method which heats and cools the semiconductor wafer in a short time with the electron beam irradiation. Thus, it is possible to realize a light-emitting diode chip which has a stable chip form with little chip loss.

Also, the semiconductor device may be a transistor or an integrated circuit thereof.

Thereby, a chip where the semiconductor device is formed is manufactured of a semiconductor wafer by the separation method which heats and cools the semiconductor wafer in a short time with the electron beam irradiation. Thus, it is possible to realize a transistor and the integrated circuit chip thereof which have a stable chip form with little chip loss.

As it is evident from the explanations above, the substrate and the dividing method according to the present invention are capable of preventing chip breaking and manufacturing chips in a reproducible square-like form. Also, the chip cost can be reduced. And, a semiconductor laser element whose threshold current is low can be manufactured. Furthermore, a high-power semiconductor laser element which prevents a catastrophic optical damage from occurring can be manufactured with a low cost.

### FURTHER INFORMATION ABOUT TECHNICAL BACKGROUND TO THIS APPLICATION

The disclosure of Japanese Patent Application No. 2003-288751 filed on Aug. 7, 2003 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is an outside drawing showing the conventional cleavage method for a nitride semiconductor wafer;

FIG. 1B is a cross-sectional drawing showing the conventional cleavage method for the nitride semiconductor wafer;

FIG. 2 is an outside drawing showing the conventional chip separation method for the nitride semiconductor wafer;

FIG. 3A is an outside drawing showing the cleavage method for a nitride semiconductor wafer according to the first embodiment of the present invention;

FIG. 3B is a cross-sectional drawing showing the cleavage method for the nitride semiconductor wafer according to the first embodiment;

FIG. 4 is an outside drawing showing the cleavage method for a nitride semiconductor wafer according to the second embodiment of the present invention;

FIG. 5A is an outside drawing showing the cleavage method for a nitride semiconductor wafer according to the third embodiment of the present invention;

FIG. 5B is a cross-sectional drawing showing the cleavage method for the nitride semiconductor wafer according to the third embodiment;

FIG. 6 is an outside drawing showing the cleavage method for a nitride semiconductor wafer according to the fourth embodiment of the present invention;

FIG. 7A is an outside drawing showing the structure of a semiconductor laser element according to the fifth embodiment of the present invention;

FIG. 7B is a cross-sectional drawing showing the structure of the semiconductor laser element according to the fifth embodiment;

FIG. 8 is an outside drawing showing the chip separation method for a nitride semiconductor wafer according to the sixth embodiment of the present invention;

FIG. 9 is an outside drawing showing the structure of a nitride semiconductor chip according to the seventh embodiment of the present invention;

FIG. 10 is an outside drawing showing the chip separation method for a nitride semiconductor wafer according to the eighth embodiment of the present invention; and

FIG. 11 is an outside drawing showing the structure of a nitride semiconductor chip according to the ninth embodiment of the present invention.

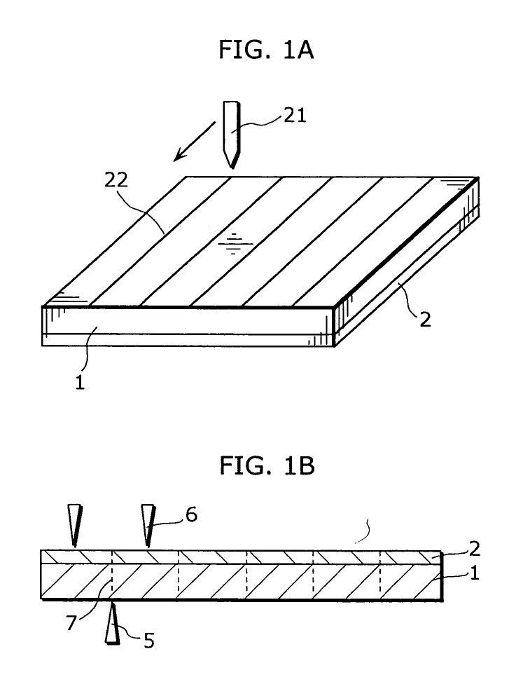

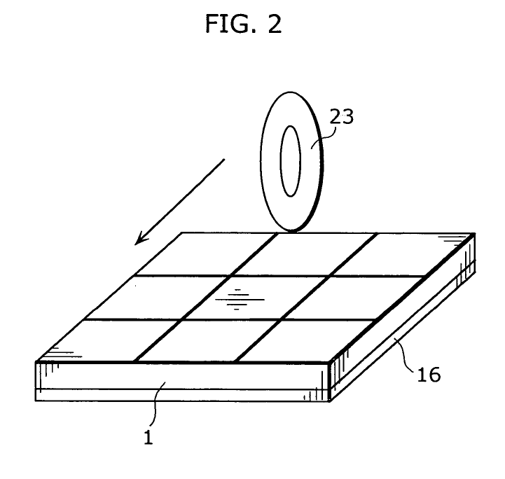

### DESCRIPTION OF THE PREFERRED EMBODIMENT(S)

A semiconductor device and a method for dividing a substrate according to the embodiments of the present invention will be explained in reference to the drawings as following.

(First Embodiment)

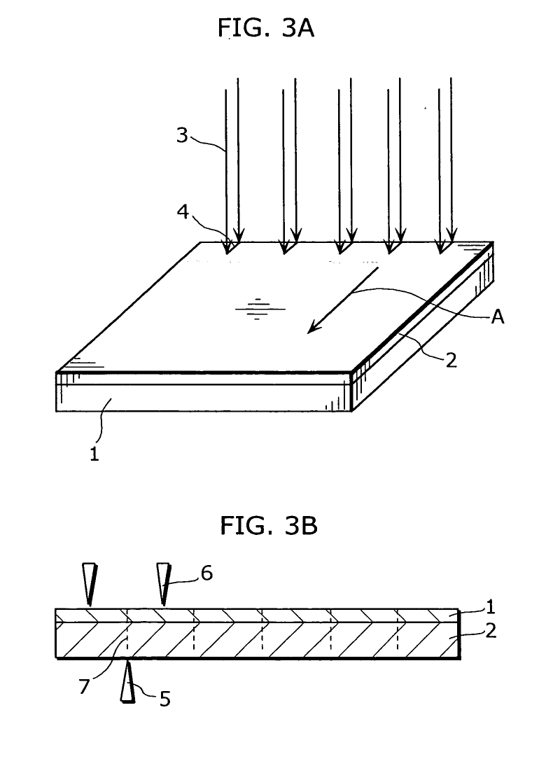

FIG. 3A is an outside drawing showing the cleavage method for a nitride semiconductor wafer according to the first embodiment of the present invention. And, FIG. 3B is a cross-sectional drawing showing the cleavage method for the nitride semiconductor wafer according to the first embodiment.

First, as shown in FIG. 3A, an epitaxial growth layer 2 is formed on a SiC substrate 1, and an InGaAIN violet semiconductor laser element which is a semiconductor device is formed. The epitaxial growth layer 2 specifically includes: an n-type InGaAIN cladding layer, an InGaAIN active layer and a p-type InGaAIN cladding layer. And, an InGaAIN active layer generates a violet laser oscillation at 405 nm. The p-type InGaAIN cladding layer is formed as the surface of the epitaxial growth layer 2, and a patterned p-type ohmic electrode, which is made of, for example, Ni/Au and the like is formed on the p-type InGaAIN cladding layer. Next, after the back surface of the SiC substrate 1 on which the epitaxial growth layer 2 is formed is polished until the thickness of the SiC substrate 1 becomes, for example, 100 μm, an n-type ohmic electrode which is made of, for example, Ni/Au and the like is formed on the SiC substrate 1. Here, the example of using a SiC substrate is described. In the case of using a sapphire substrate, as the substrate does not have an electrical conductivity, after the p-type InGaAIN cladding layer and the InGaAIN active layer are selectively removed, the n-type ohmic electrode which is made of, for example, Ti/Al and the like is formed on the n-type InGaAIN cladding layer which is exposed on the surface of the epitaxial growth layer 2. Next, as shown in FIG. 3A, the surface of the epitaxial growth layer 2 of the end part of the nitride semiconductor wafer is linear-scanned a plurality of times by an electron beam 3 so that scanning lines are parallel. The electron beam 3 is irradiated in the direction of “a” axis (<11-20> direction and “A” as shown in FIG. 3A) which is the cleavage direction of the InGaAIN layer with the interval of the resonant length of the semiconductor laser element. The irradiation of the electron beam 3 forms a scribe line 4 heading to the direction of “a” axis in the end part of the nitride semiconductor wafer. The scribe line 4 is generated with the origin of a crack which is generated by heating and cooling the surface of the nitride semiconductor wafer with the irradiation of the electron beam 3 in a short time.

Next, as shown in FIG. 3B, a bar-shaped nitride semiconductor wafer including a plurality of semiconductor laser chips is formed by (i) putting an edge jig 5 on the scribe line 4 of the surface of the epitaxial growth layer 2, (ii) adding pressure on the back surface of the SiC substrate 1 with an edge jig 6 and (iii) cleaving the nitride semiconductor wafer with the origin of the scribe line 4. The cleaved facet 7 of the edge face of the bar-shaped nitride semiconductor wafer which is exposed by the cleavage can be used as an end mirror of the semiconductor laser element. By repeating such process as described above, for example, it is possible to form a mirror for forming a resonator of the semiconductor laser element. Then, semiconductor laser chips can be obtained by repeatedly performing (a) a coating for improving the edge face reflectivity for the cleaved facet 7 of the bar-shaped nitride semiconductor wafer and (b) the above mentioned cleavage process.

Here, the current value and the scanning speed of the electron beam is optimized so that the scribe line is formed parallel to the cleavage direction and selectively on the surface of the epitaxial growth layer of the end part of the nitride semiconductor wafer. For example, the electron beam is irradiated on the surface of the semiconductor wafer with the conditions of the acceleration voltage of 60 kV and the beam current of 15 mA.

Thus, according to the first embodiment, the scribe line is generated by scanning the surface of the epitaxial growth layer of the end part of the nitride semiconductor wafer with the electron beam. And, the cleavage is performed with the origin of the scribe line. In comparison to the conventional case where the cleavage is performed by forming a ditch in the back surface of the substrate with the diamond scriber, the cleavage method for the nitride semiconductor wafer with less possibility of causing chip breaking can be realized. Also, the flat cleaved facet can be obtained by realizing the cleavage along the cleaved facet with a high accuracy. And, the cleavage method for the nitride semiconductor wafer capable of manufacturing the semiconductor laser element whose mirror reflectivity is high and threshold current is low can be realized.

In addition, when performing the cleavage, before irradiating the electron beam, a viscous sheet can be attached to the back surface of the nitride semiconductor wafer where the electron beam irradiation is not performed. After the electron beam irradiation and cleavage process, the nitride semiconductor wafer can be separated in a bar form by pulling the sheet. Here, in order to prevent the charge up of the nitride semiconductor wafer, it is desirable that the viscous sheet has an electrical conductivity.

Moreover, according to the first embodiment, the substrate and the epitaxial growth layer can be made of a GaAs compound semiconductor.

Furthermore, according to the first embodiment, after the electron beam irradiation and cleavage are performed in the state where the back surface of the nitride semiconductor wafer where the electron beam irradiation is not performed is attached to the film-like sheet, the cleavage can be performed by pulling the sheet and separating the nitride semiconductor wafer in a bar form.

(Second Embodiment)

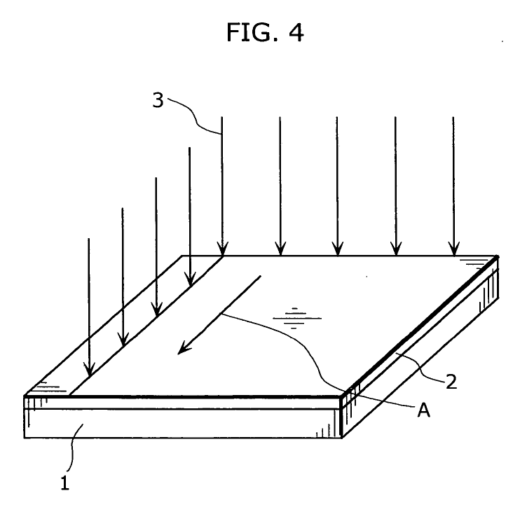

FIG. 4 is an outside drawing showing the cleavage method for a nitride semiconductor wafer according to the second embodiment.

According to the cleavage method of the second embodiment, in the process of forming the scribe line in the end part of the nitride semiconductor wafer by irradiating an electron beam according to the first embodiment as shown in FIG. 3A, the surface of the epitaxial growth layer is scanned with the electron beam so that the scanning lines are across the nitride semiconductor wafer.

First, as shown in FIG. 4, as well as the first embodiment, an epitaxial growth layer 2 is formed on a SiC substrate 1, and a violet InGaAIN semiconductor laser element which is a semiconductor device is formed. A p-type InGaAIN cladding layer is formed as the surface of the epitaxial growth layer 2, and a patterned p-type ohmic electrode which is made of, for example, Ni/Au and the like is formed on the p-type InGaAIN cladding layer. Next, after the back surface of the SiC substrate 1 on which the epitaxial growth layer 2 is formed is polished until the thickness of the SiC substrate 1 becomes, for example, 100 μm, an n-type ohmic electrode which is made of, for example, Ni/Au and the like is formed on the SiC substrate 1. Here, the example of using a SiC substrate is described. In the case of using a sapphire substrate, as the substrate does not have an electrical conductivity, after the p-type InGaAIN cladding layer and the InGaAIN active layer are selectively removed, the n-type ohmic electrode which is made of, for example, Ti/Al and the like is formed on the n-type In GaAIN cladding layer which is exposed on the surface of the epitaxial growth layer 2.

Next, the surface of the epitaxial growth layer 2 of the nitride semiconductor wafer is scanned with an electron beam 3 a plurality of times so that the scanning lines are parallel to the cleaved facet across the nitride semiconductor wafer. After the scanning, the nitride semiconductor wafer is separated in the cleaved facet, and a bar-shaped nitride semiconductor wafer which includes a plurality of semiconductor laser chips is formed. This separation in the cleaved facet is performed with the origin of a crack generated by heating and cooling the surface of the nitride semiconductor wafer in a short time with the irradiation of the electron beam 3. By repeating such process as described above, it is possible to form, for example, a mirror for forming a resonator of the semiconductor laser element. Then, semiconductor laser chips can be obtained by repeatedly performing (a) a coating for improving the edge face reflectivity for the cleaved facet of the bar-shaped nitride semiconductor wafer and (b) the above mentioned cleavage process.

Thus, according to the second embodiment, the cleavage is performed only by the electron beam irradiation without performing the process of putting the edge jig. Thus, compared to the first embodiment, the easier cleavage can be realized, and the cleavage method for the nitride semiconductor wafer capable of reducing the chip cost can be realized.

(Third Embodiment)

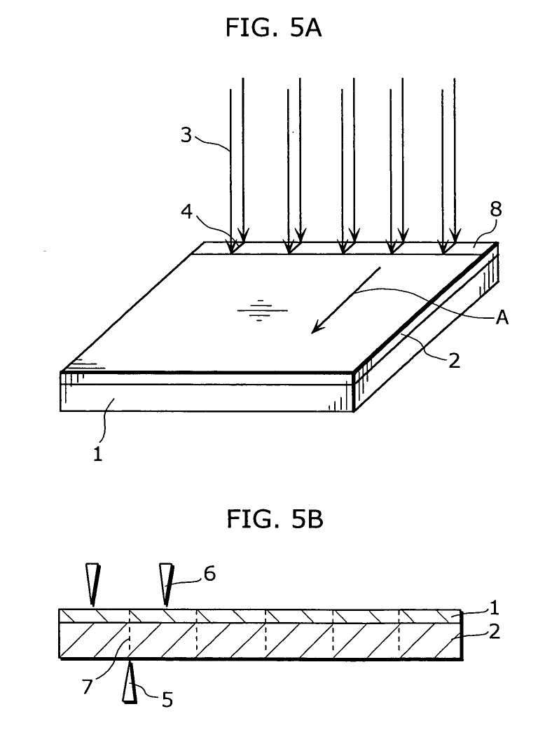

FIG. 5A is an outside drawing showing a cleavage method for a nitride semiconductor wafer according to the third embodiment of the present invention. And, FIG. 5B is a cross-sectional drawing showing a cleavage method for a nitride semiconductor wafer according to the third embodiment.

According to the cleavage method of the third embodiment, in the first embodiment as shown in FIG. 3A and FIG. 3B, by forming a metal thin film on the end part of the nitride semiconductor wafer before irradiating an electron beam, the electron beam is prevented from being bent by the charge up, and more accurate linear-scanning with the electron beam is made possible.

First, as shown in FIG. 5A, as well as the first embodiment, an epitaxial growth layer 2 is formed on a SiC substrate 1, and an violet InGaAIN semiconductor laser element which is a semiconductor device and oscillates at 405 nm is formed. The p-type InGaAIN cladding layer is formed as the surface of the epitaxial growth layer 2, and a patterned p-type ohmic electrode which is made of, for example, Ni/Au and the like is formed on the p-type InGaAIN cladding layer. Although it is not shown in the drawings, the p-type ohmic electrode is formed with the width of 100 μm in the stripe form, perpendicularly to the cleavage direction. Next, in addition to the p-type ohmic electrode, a metal thin film 8 such as an Au thin film with the width of more than several mm is formed on the end part of the nitride semiconductor wafer for preventing the charge up of the nitride semiconductor wafer. Next, after the back surface of the SiC substrate 1 on which the epitaxial growth layer 2 is formed is polished until the thickness of the SiC substrate 1 becomes, for example, 100 μm, an n-type ohmic electrode which is made of, for example, Ni/Au and the like is formed on the SiC substrate 1. Here, the example of using a SiC substrate is described. In the case of using a sapphire substrate, as the substrate does not have an electrical conductivity, after the p-type InGaAIN cladding layer and the InGaAIN active layer are selectively removed, the n-type ohmic electrode which is made of, for example, Ti/Al is formed on the surface of the exposed n-type InGaAIN cladding layer. Next, the metal thin film 8 which has been formed on the end part of the nitride semiconductor wafer is linear-scanned a plurality of times by an electron beam 3 so that the scanning lines are parallel as shown in FIG. 5A. By the scanning of the electron beam 3, as well as the first embodiment, a scribe line 4 which heads to the direction of “a” axis(“A” in FIG. 5A) is formed in the end part of the nitride semiconductor wafer. The scribe line 4 is generated with the origin of a crack which is generated by the heating and cooling the surface of the nitride semiconductor wafer in a short time with the electron beam 3.

Next, as shown in FIG. 5B, by putting an edge jig 5 on the scribe line 4 on the surface of the epitaxial growth layer 2 and adding pressure on the back surface of the SiC substrate 1 with the edge jig 6, a cleavage of the nitride semiconductor wafer is performed with the origin of the scribe line 4, and a bar-shaped nitride semiconductor wafer including a plurality of semiconductor laser chips is formed. By repeating such process as described above, it is possible to form, for example, a mirror for forming a resonator of the semiconductor laser element. Then, semiconductor laser chips can be obtained by repeatedly performing (a) a coating for improving the edge face reflectivity for the cleaved facet 7 of the bar-shaped nitride semiconductor wafer and (b) the above mentioned cleavage process.

Thus, according to the third embodiment, in the electron beam irradiation the electron beam is irradiated so that the irradiation line is parallel to the cleavage direction of the epitaxial growth layer without being bent. And, the cleavage is performed with the origin of the scribe line which is generated in the end part of the nitride semiconductor wafer by such electron beam irradiation. Therefore, compared to the first embodiment, more accurate cleavage along the cleaved facet can be realized, and a semiconductor laser element having an even flatter cleaved facet can be obtained. Thereby, the cleavage method for the nitride semiconductor wafer capable of manufacturing the semiconductor laser element whose mirror reflectivity is even higher and threshold current is even lower can be realized. For example, in the case of cleaving a nitride semiconductor wafer by irradiating an electron beam not on the epitaxial growth layer but on a substrate of a low electrical conductivity such as a sapphire substrate, a charge up easily occurs, and the electron beam is easily bent in the electron beam irradiation. Consequently, substantial effects are displayed in the case of cleaving the nitride semiconductor wafer by irradiating an electron beam on the substrate of a low electrical conductivity.

Also, according to the third embodiment, a metal thin film is formed in the point scribing part on the surface of the epitaxial growth layer. Thereby, the cleavage method for the nitride semiconductor wafer which is capable of performing a point scribe with less electron beam current can be realized.

In addition, although the electron beam irradiation is limited to only the metal thin film which is on the end part of the nitride semiconductor wafer according to the third embodiment, the semiconductor laser element having the similarly flat cleaved facet can be obtained even if the linear-scanning of the electron beam is performed so that the scanning lines are across all the top part of the cleaved facet. And, the electron beam irradiation is performed on the surface of the epitaxial growth layer where the metal thin film is not formed, so that the irradiation lines are across the nitride semiconductor wafer. Here, the metal thin film can be formed not only on the end part of the nitride semiconductor wafer, but also in all the parts of the nitride semiconductor wafer where an electron beam passes.

(Fourth Embodiment)

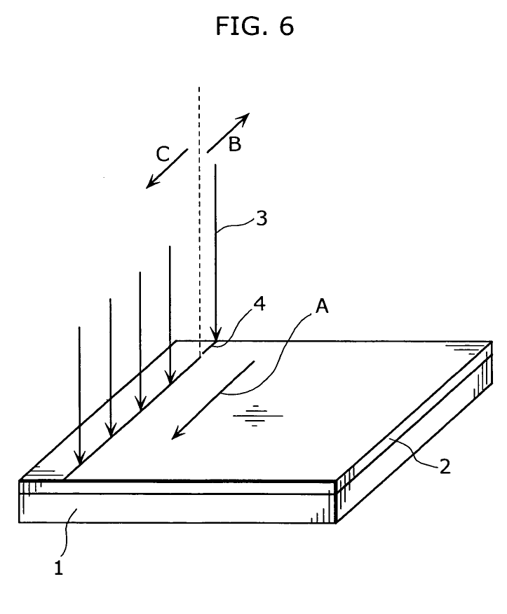

FIG. 6 is an outside drawing showing a cleavage method for a nitride semiconductor wafer according to the fourth embodiment of the present invention.

According to the cleavage method of the fourth embodiment, in the process of forming the scribe line in the end part of the nitride semiconductor wafer by the electron beam irradiation according to the first embodiment as shown in FIG. 3A, after the scribe line is formed by irradiating an electron beam of a high current in the end part of the nitride semiconductor wafer, the nitride semiconductor wafer is scanned by the electron beam of a varied current, so that the irradiation lines are across the nitride semiconductor wafer.

First, as shown in FIG. 6, as well as the first embodiment, an epitaxial growth layer 2 is formed on a SiC substrate 1, and an violet InGaAIN semiconductor laser element which is a semiconductor device and oscillates at 405 nm is formed. A p-type InGaAIN cladding layer is formed as the surface of the epitaxial growth layer 2, and a patterned p-type ohmic electrode which is made of, for example, Ni/Au and the like is formed on the p-type InGaAIN cladding layer. Next, after the back surface of the SiC substrate 1 on which the epitaxial growth layer 2 is formed is polished until the thickness of the SiC substrate 1 becomes, for example, 100 μm, an n-type ohmic electrode which is made of, for example, Ni/Au and the like is formed on the SiC substrate 1. Here, the example of using a SiC substrate is described. In the case of using a sapphire substrate, as the substrate does not have an electrical conductivity, after the p-type InGaAIN cladding layer and the InGaAIN active layer are selectively removed, the n-type ohmic electrode which is made of, for example, Ti/Al and the like is formed on the n-type InGaAIN cladding layer which is exposed on the surface of the epitaxial growth layer 2.

Next, the part as shown in FIG. 6, that is, the surface of the epitaxial growth layer 1 of the end part of the nitride semiconductor wafer is linear-scanned a plurality of times by an electron beam 3 so that scanning lines are parallel. In the scanning of the electron beam 3, the electron beam of a high current is irradiated, and a scribe line 4 is generated in the end part of the nitride semiconductor wafer. The scribe line 4 is generated with the origin of a crack which is generated by heating and cooling the surface of the nitride semiconductor wafer with the irradiation of the electron beam 3 in a short time. Next, the current of the electron beam is decreased, and the “C” part as shown in FIG. 6 is scanned by the electron beam 3 of a low current a plurality of times so that the scanning lines are parallel to the cleaved facet. After the scanning, the nitride semiconductor wafer is separated in the cleaved facet, and a bar-shaped nitride semiconductor wafer including a plurality of semiconductor laser chips is formed. By repeating such process as described above, for example, it is possible to form a mirror for forming a resonator of the semiconductor laser element. Then, semiconductor laser chips can be obtained by repeatedly performing (a) a coating for improving the edge face reflectivity for the cleaved facet of the bar-shaped nitride semiconductor wafer and (b) the above mentioned cleavage process.

Thus, according to the fourth embodiment, the cleavage is performed only by the electron beam irradiation, without the process of putting the edge jig. Thereby, compared to the first embodiment, the easier cleavage can be realized, and the cleavage method for the nitride semiconductor wafer capable of reducing the chip cost can be realized.

Also, according to the fourth embodiment, after the scribe line is generated in the end part of the nitride semiconductor wafer, the nitride semiconductor wafer is scanned by the electron beam so that the scanning lines are parallel to the cleaved facet, across the nitride semiconductor wafer. Thus, even in the case where the scanning lines of the electron beam deviate from the straight lines, the cleavage is easily performed in the cleavage direction of the nitride semiconductor wafer. Consequently, the cleavage method of the nitride semiconductor wafer which is capable of obtaining chips having the cleaved facet with a better linearity can be realized.

(Fifth Embodiment)

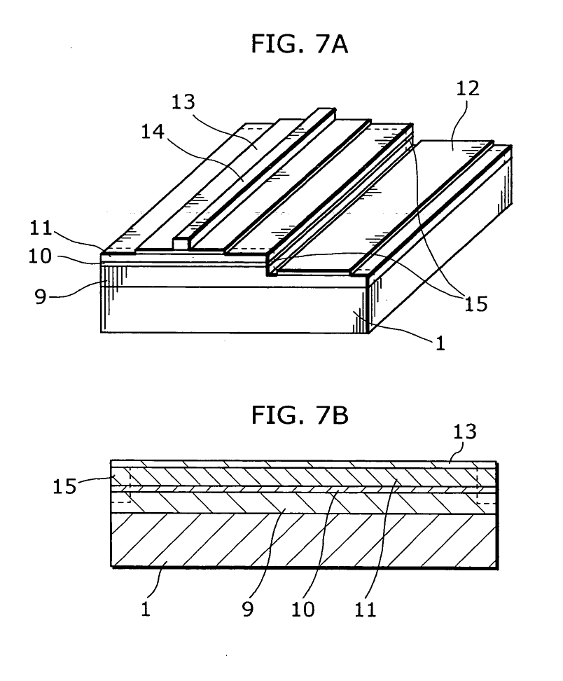

FIG. 7A is an outside drawing showing a structure of a semiconductor laser element according to the fifth embodiment. And, FIG. 7B is a cross-sectional drawing showing a structure of a semiconductor laser element according to the fifth embodiment.

The fifth embodiment shows an example of the semiconductor laser element which is a semiconductor device which can be manufactured using the cleavage method as described in the first, second, third and fourth embodiments. The semiconductor laser element has a waveguide stripe structure. On a SiC substrate 1, an n-type InGaAIN layer 9, an InGaAIN quantum well active layer 10 and a p-type InGaAIN layer 11 are sequentially laminated. And, a violet laser oscillation at 405 nm can be obtained from the quantum well active layer 10. Although it is not shown in the drawing, a dielectric film such as SiO₂ is formed for controlling light containment on the side wall of the semiconductor laser waveguide stripe 14. Although the SiC substrate is shown here, but a sapphire substrate can be used as well. In the neighborhood of the cleaved facet of the semiconductor laser element, a part 15 whose quantum well structure is disordered is formed. In the disordered part 15, due to the change of precipitousness of the composition of the quantum well structure, the band gap is larger than the band gap which corresponds to the luminous wavelength which is formed at the quantum level of the quantum Well.

Next, a manufacturing method of a semiconductor laser element which has the above mentioned structure will be explained.

First, on the SiC substrate 1, the n-type InGaAIN layer 9, the InGaAIN quantum well active layer 10 and the p-type InGaAIN layer 11 are sequentially laminated. Next, the waveguide stripe structure is formed for the p-type InGaAIN layer 11. Then, the rest of the p-type InGaAIN layer 11 and the InGaAIN active layer 10 are selectively removed by the reactive ion etching which uses, for example, Cl₂ gas. After that, respectively in a stripe form, a p-type ohmic electrode 13 which is made of, for example, Ni/Au and the like is formed on the surface of the p-type InGaAIN layer 11, and an n-type ohmic electrode 12 which is made of, for example, Ti/Al and the like is formed on the n-type InGaAIN layer 9.

Next, by using the cleavage method explained in the first, second, third and fourth embodiments, the nitride semiconductor wafer is cleaved perpendicularly to the semiconductor laser waveguide stripe 14, and the cleaved facet is formed. In order for the cleaved facet to increase the edge face reflectivity, it can be coated by, for example, a dielectric multilayer. Here, preceding the electron beam irradiation, on the region of several μm width including the part of the epitaxial layer which is formed on the SiC substrate 1, said part being an area where the electron beam is irradiated, impurities such as Zn, Si are diffused or added by ion injection, or a thin film including impurities such as ZnO is formed parallel to the cleavage direction. Thus, due to the heating or thermal degradation in the electron beam irradiation, the above mentioned impurities such as Zn and Si diffuse in the region which is surrounded by the dotted line in FIG. 7A, that is, the region of several μm deep from the cleaved facet. And, the part 15 where the quantum well structure is disordered is formed.

Thus, according to the fifth embodiment, the semiconductor laser element has the following structure. In the structure the part where the quantum well structure is disordered is added to the semiconductor laser element which is manufactured by the above mentioned first, second, third and fourth embodiments. Thereby, the light density of the neighborhood of the edge surface of the semiconductor laser element decreases, and the semiconductor laser which prevents a catastrophic optical damage from occurring can be realized. Moreover, although the formation of the disordered part as described above has been conventionally realized by performing the thermal process before the cleavage process, the cleavage process and the thermal process can be performed at the same time, according to the semiconductor laser element of the fifth embodiment. As a result, the high-power semiconductor laser element which prevents the catastrophic optical damage from occurring can be manufactured by the manufacturing process including a few processes. At the same time, the cleavage method for the nitride semiconductor wafer which is capable of manufacturing the high-power semiconductor laser element which prevents the catastrophic optical damage from occurring with a low cost can be realized.

(Sixth Embodiment)

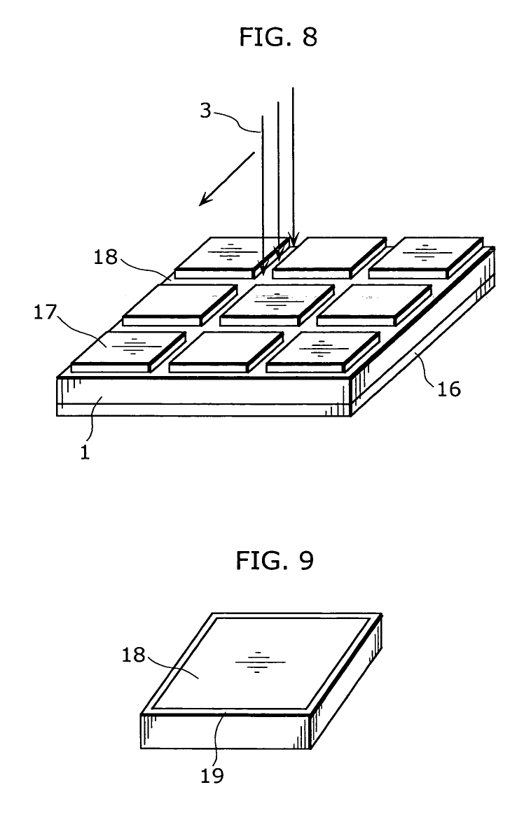

FIG. 8 is an outside drawing showing a chip separation method for a nitride semiconductor wafer according to the sixth embodiment of the present invention.

First, as shown in FIG. 8, an InGaAIN epitaxial growth layer 16 is formed on a SiC substrate 1 by, for example, the MOCVD method. This InGaAIN epitaxial growth layer 16 forms a light-emitting diode and a field effect transistor integrated circuit which are semiconductor devices. In the case of forming a light-emitting diode, the InGaAIN epitaxial growth layer 16 specifically includes an n-type InGaAIN layer, an InGaAIN active layer and a p-type InGaAIN layer. And, the InGaAIN active layer emits a blue light at 470 nm by a current injection. In the case of forming a field effect transistor, an n-type AlGaA layer is formed on an undoped GaN layer. After the completion of a device formation process such as an electrode formation, the SiC substrate 1 is made a thin film by polishing and the like. Next, as shown in FIG. 8, a metal thin film 18 such as an Au thin film is formed on the surface of the SiC substrate 1 so that the surface of the SiC substrate 1 is covered. After that, an insulating film 17 such as a patterned photoresist and a patterned dielectric insulating film are formed on the SiC substrate 1 so that the surface of the SiC substrate 1 other than the part where an electron beam is irradiated for performing a chip separation is covered. The part of the surface of the SiC substrate 1 which is not covered by the insulating film 17, that is, the part where the metal thin film 18 is exposed is linear-scanned a plurality of times by an electron beam 3 in the “xy” direction so that the scanning lines cross each other. And, the nitride semiconductor wafer is separated into chips. It is desirable that at least one of the scanning directions of the electron beam 3 is the “a” axis (<11-20>direction) direction which is the cleavage direction of the SiC substrate 1. The chip separation is performed with the origin of a crack generated by heating and cooling the surface of the nitride semiconductor wafer in a short time by the electron beam 3 irradiation. After the chip separation, the insulating film 17 is removed using, for example, an organic solvent or acid.

Here, as well as the first embodiment, the current value and the scanning speed of the electron beam are optimized so that the chips can be manufactured in a square-like form by the chip separation and the chips cannot be broken easily.

Thus, according to the sixth embodiment, a crack is generated in the nitride semiconductor wafer by performing a scanning of an electron beam, and the chip separation is performed with the origin of the crack. Therefore, the chip separation method for the nitride semiconductor wafer which is capable of preventing chips from breaking and manufacturing chips in a reproducible square-like form can be realized, in said nitride semiconductor wafer, for example, a light-emitting diode or a field effect transistor are formed. Also, it is not necessary to consider loss in the cleavage part of the nitride semiconductor wafer. As a result, compared to the conventional case of dicing using the diamond blade, the total number of chips that can be manufactured of the nitride semiconductor wafer can be increased. Thereby, the chip separation method capable of reducing the chip cost can be realized.

In addition, according to the sixth embodiment, a metal thin film is formed on the surface of the nitride semiconductor wafer. Thus, in the electron beam irradiation the electron beam is irradiated on the nitride semiconductor wafer without being bent, and the electron beam scanning can be performed in the form similar to a straight line. Thereby, the chip separation method for the nitride semiconductor wafer capable of making the chip form a reproducible shape similar to a square can be realized. For example, in the case of performing a chip separation by irradiating an electron beam on a substrate of a low electrical conductivity such as a sapphire substrate, a charge up easily occurs, and the electron beam is easily bent in the electron beam irradiation. Consequently, substantial effects are displayed in the case of performing a chip separation by irradiating an electron beam on the substrate of the low electrical conductivity.

In addition, according to the sixth embodiment, the insulating film is formed in the part of the surface of the nitride semiconductor wafer other than the part where the electron beam passes. Thus, the electron beam is easily irradiated on the surface of the nitride semiconductor wafer where the metal thin film is exposed by spotting an insulating film. And, the electron beam scanning can be performed in the form similar to a straight line. Thereby, the chip separation method for the nitride semiconductor wafer capable of making the chip form a reproducible shape similar to a square can be realized.

In addition, when performing the chip separation, before irradiating the electron beam, a viscous sheet can be attached to the back surface of the nitride semiconductor wafer where the electron beam irradiation is not performed. After the electron beam irradiation process, the the chip separation can be performed by pulling the sheet.

(Seventh Embodiment)

FIG. 9 is an outside drawing showing a structure of a nitride semiconductor chip according to the seventh embodiment.

The seventh embodiment shows an example of the nitride semiconductor chip which can be manufactured by using the chip separation method as shown in the sixth embodiment. In such semiconductor chip as described above, the followings and the like are formed: (a) a blue light-emitting diode (470 nm emission) which is a semiconductor device which is formed by the sequential lamination of an n-type InGaAIN layer, an InGaAIN active layer and a p-type InGaAIN layer on a SiC substrate and (b) a field effect transistor integrated circuit which is a semiconductor device which is formed by the sequential lamination of an undoped GaN layer and an n-type AlGaN layer on the SiC substrate. Such semiconductor chip as described above includes a thermal degradation layer 19 which has a disordered structure which is formed by performing a thermal degradation such as nitrogen exit and crystalline turbulence in the end part of the semiconductor chip where an electron beam is irradiated in the chip separation process.

Thus, according to the seventh embodiment, the nitride semiconductor chip which is manufactured by the nitride semiconductor wafer chip separation method of the sixth embodiment which is capable of performing a chip separation while (a) preventing chips from breaking in the nitride semiconductor wafer where, for example, a light-emitting diode or a field effect transistor are formed and (b) manufacturing chips in a reproducible square-like form can be realized. Also, it is not necessary to consider loss in the cleavage part of the nitride semiconductor wafer. As a result, compared to the conventional case of dicing using the diamond blade, the total number of chips that can be manufactured of the nitride semiconductor wafer can be increased. Thereby, the nitride semiconductor chip which is manufactured by the nitride semiconductor wafer chip separation method capable of reducing the chip cost can be realized.

Also, according to the seventh embodiment, in the thermal degradation layer part, the passivation insulating film is removed.

Moreover, the thermal degradation layer can be formed on the back side of the substrate where the circuit is not formed, that is, the epitaxial layer is not formed.

(Eighth Embodiment)

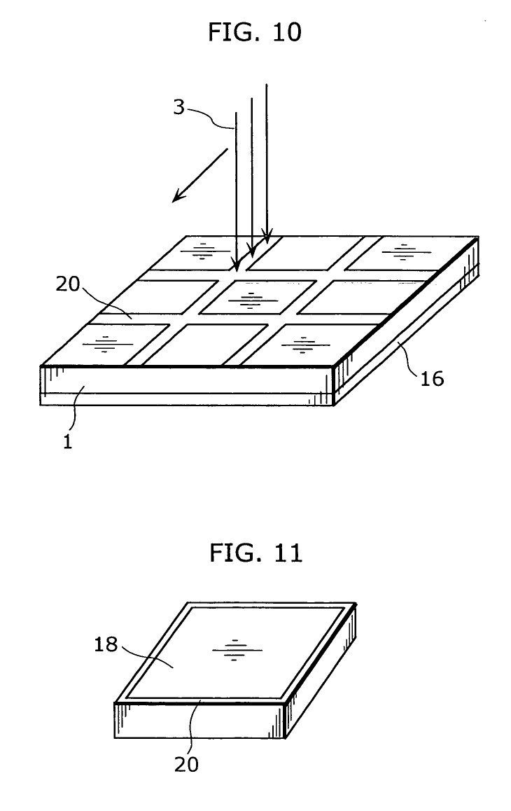

FIG. 10 is an outside drawing showing a nitride semiconductor wafer chip separation method according to the eighth embodiment of the present invention.

First, as shown in FIG. 10, as well as the sixth embodiment, an InGaAIN epitaxial growth layer 16 is formed on a SiC substrate 1. The InGaAIN epitaxial growth layer 16 forms a light-emitting diode which is a semiconductor device which emits a blue light at 470 nm or a field effect transistor integrated circuit which is a semiconductor device. After the completion of a device formation process such as an electrode formation, the SiC substrate 1 is made a thin film by polishing and the like. Next, as shown in FIG. 10, a patterned metal thin film 20 such as an Au thin film is formed on the surface of the SiC substrate 1 so that the part of the surface of the SiC substrate 1 where an electron beam is irradiated for chip separation is covered. The metal thin film 20 is linear-scanned a plurality of times by an electron beam 3 in the “xy” direction so that the scanning lines cross each other. And, the nitride semiconductor wafer is separated into chips. It is desirable that at least one of the scanning directions of the electron beam 3 is the “a” axis (<11-20>direction) direction which is the cleavage direction of the SiC substrate 1. The chip separation is performed with the origin of a crack generated by heating and cooling the surface of the nitride semiconductor wafer in a short time by the electron beam 3 irradiation.

Here, as well as the sixth embodiment, the current value and the scanning speed of the electron beam are optimized so that the chips can be manufactured in the square-like form by the chip separation and the chips cannot be broken easily.

Thus, according to the eighth embodiment, the chip separation method for the nitride semiconductor wafer which is capable of (a) preventing chips from breaking in the nitride semiconductor wafer where, for example, a light-emitting diode or a field effect transistor are formed and (b) manufacturing chips in a reproducible square-like form can be realized. Also, it is not necessary to consider loss in the cleavage part of the nitride semiconductor wafer. As a result, compared to the conventional case of dicing using the diamond blade, the total number of chips that can be manufactured of the nitride semiconductor wafer can be increased. Thereby, the chip separation method capable of reducing the chip cost can be realized.

In addition, according to the eighth embodiment, a metal thin film is formed on the part of the surface of the nitride semiconductor wafer where the electron beam passes. Thus, in the electron beam irradiation the electron beam is irradiated on the nitride semiconductor wafer without being bent, and the electron beam scanning can be performed in the form similar to a straight line. Thereby, the chip separation method for the nitride semiconductor wafer capable of making the chip form a reproducible shape similar to a square can be realized. Moreover, the electron beam is easily irradiated on the metal thin film part by spotting the metal thin film. And, the electron beam scanning can be performed in the form similar to a straight line. Thereby, the chip separation method for the nitride semiconductor wafer capable of making the chip form a reproducible shape similar to a square can be realized.

In addition, when performing the chip separation, before irradiating the electron beam, a viscous sheet can be attached to the back surface of the nitride semiconductor wafer where the electron beam irradiation is not performed. After the electron beam irradiation process, the chip separation can be performed by pulling the sheet.

The metal thin film can be further formed in a part of the surface of the nitride semiconductor wafer where the electron beam irradiation is performed other than the part where the electron beam passes. For example, the metal thin film can be formed on the whole area of the surface of the nitride semiconductor wafer where the electron beam irradiation is performed.

(Ninth Embodiment)

FIG. 11 is an outside drawing showing a structure of the nitride semiconductor chip according to the ninth embodiment of the present invention.

The ninth embodiment shows an example of the nitride semiconductor chip which can be manufactured using the chip separation method as shown in the eighth embodiment. On the end part of such semiconductor chip as described above, for example, a metal thin film 20 such as an Au thin film is formed. Also, in the part of the surface of the above mentioned semiconductor chip where the metal thin film 20 is not formed, as well as the sixth embodiment, a blue light-emitting diode (470 nm emission) which is a semiconductor device, a field effect transistor integrated circuit which is a semiconductor device and the like are formed. Here, on the metal thin film 20, the passivation insulating film is removed. In addition, the substrate materials are for example, GaAs, GaN/sapphire, GaN/SiC and the like.

Thus, according to the ninth embodiment, the nitride semiconductor chip which is manufactured by the chip separation method for the nitride semiconductor wafer which is capable of preventing chips from breaking in the nitride semiconductor wafer and manufacturing chips in a reproducible square-like form can be realized. Also, it is not necessary to consider loss in the cleavage part of the nitride semiconductor wafer. As a result, compared to the conventional case of dicing using the diamond blade, the total number of chips that can be manufactured of the nitride semiconductor wafer can be increased. Thereby, the chip separation method capable of reducing the chip cost can be realized.

The metal thin film can be selectively formed on the back side of the substrate where the circuit is not formed.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

For example, the SiC substrate and the sapphire substrate which are used in the embodiments as shown in the above mentioned FIG. 3-FIG. 11 can have any plane direction. Also, such SiC substrate and sapphire substrate as described above can be cleaved in any plane direction. For example, a plane direction for a representative plane such as (0001) plane with an off-angle can be used. Here, such substrates as described above can be GaN substrates. In addition, an InGaAIN layer can have any composition rate. And, the crystal growth method can not only be the MOCVD method, but also, for example, a Molecular Beam Epitaxy (MBE) method or a Hydride Vapor Phase Epitaxy (HVPE) method. Moreover, the InGaAIN layer can include group V elements such as As and P or group III elements such as B as constituent elements. Furthermore, the present invention is not limited to the cleavage method or the chip separation method for the nitride semiconductor wafer, but it can be applied, using a III-V compound semiconductor such as GaAs and InP, as a cleavage method or a chip separation method for a semiconductor wafer where a semiconductor laser element, a light-emitting diode and a field effect transistor are formed. Also, the semiconductor devices such as the semiconductor laser element, the light-emitting diode and the field effect transistor can be formed not only by the crystal growth method, but also by the ion injection method.

### INDUSTRIAL APPLICABILITY

The present invention can be applied to a semiconductor device and a method for dividing a substrate, in particular, to a chip separation method and a cleavage method for a semiconductor wafer.

1. A method for dividing a substrate in which a semiconductor device is formed, the method comprising
an electron beam scanning process in which a crack is generated by scanning a main surface of the substrate with an electron beam.

2. The method for dividing the substrate according to claim 1, the method further comprising
a metal film formation process in which, before said electron beam scanning process, a metal film is formed on at least a part of the main surface of the substrate which is scanned by the electron beam.

3. The method for dividing the substrate according to claim 2,
wherein in said metal film formation process, a metal film is formed on a part of the main surface of the substrate, said part being an area where the electron beam passes.

4. The method for dividing the substrate according to claim 2,
wherein in said electron beam scanning process, the electron beam scanning is started from an end part of the substrate, and
in said metal film formation process, a metal film is formed on a main surface of an end part of the substrate which is scanned by the electron beam.

5. The method for dividing the substrate according to claim 1,
wherein in said electron beam scanning process, the main surface of the substrate is scanned with the electron beam whose current value is being changed.

6. The method for dividing the substrate according to claim 1,
wherein in said electron beam scanning process, the substrate is divided in a bar form by linear-scanning the substrate with the electron beam a plurality of times so that scanning lines are parallel.

7. The method for dividing the substrate according to claim 6, the method further comprising
a first coating process in which, after said electron beam scanning process, an edge face is coated, said edge face being exposed by the division of the substrate in the bar form.

8. The method for dividing the substrate according to claim 1, the method further comprising
an insulating film formation process in which, before said electron beam scanning process, an insulating film is formed on a part of the main surface of the substrate which is scanned by the electron beam, said part being an area where the electron beam does not pass.

9. The method for dividing the substrate according to claim 8,
wherein the insulating film is a photoresist or a dielectric insulating film.

10. The method for dividing the substrate according to claim 8, further comprising
an insulating film removing process in which the insulating film is removed after said electron beam scanning process.

11. The method for dividing the substrate according to claim 1,
wherein the semiconductor device is a semiconductor laser element.

12. The method for dividing the substrate according to claim 11, the method further comprising
an impurities addition process in which, before said electron beam scanning process, impurities are added to or a film including impurities is formed on a part of the main surface of the substrate which is scanned by the electron beam, said part being an area where the electron beam passes, and
in said electron beam scanning process, the impurities are diffused by the electron beam scanning.

13. The method for dividing the substrate according to claim 1,
wherein the substrate includes a semiconductor layer which is made of InGaAIN.

14. The method for dividing the substrate according to claim 1,
wherein the substrate includes a part which is made of SiC, sapphire or GaN.

15. The method for dividing the substrate according to claim 1,
wherein the semiconductor device is a light-emitting diode.

16. The method for dividing the substrate according to claim 1,
wherein the semiconductor device is a transistor or an integrated circuit thereof.

17. The method for dividing the substrate according to claim 1,
wherein in said electron beam scanning process, the substrate is divided in a chip form by performing a linear-scanning with the electron beam a plurality of times so that scanning lines are crossed.

18. The method for dividing the substrate according to claim 1,
wherein in said electron beam scanning process, the main surface is linear-scanned a plurality of times by the electron beam so that scanning lines are parallel, said main surface being in the end part of the substrate where the metal film is formed, and
the method for dividing the substrate further comprises a bar formation process in which, after said electron beam scanning process, the substrate is divided by adding pressure to the main surface of the substrate which has the crack and the main surface of the substrate which does not have the crack so that the substrate is formed in a bar form.

19. The method for dividing the substrate according to claim 18, the method further comprising
a second coating process in which, after the bar formation process, an edge face is coated, said edge face being exposed by the division of the substrate in the bar form.

20. The method for dividing the substrate according to claim 1, further comprising:
an attachment process, in which, before the electron beam scanning process, a viscous sheet is attached to the main surface of the substrate which is not scanned by the electron beam; and
a pulling formation process in which, after the electron beam scanning process, the viscous sheet is pulled so that the substrate is divided.

21. The method for dividing the substrate according to claim 20,
wherein the viscous sheet is an electrically conductive viscous sheet.

22. A semiconductor device which is formed by a substrate including a thermal degradation layer in an end part.

23. The semiconductor device according to claim 22,
wherein the substrate further includes a metal film which is formed on the end part of the substrate.

24. The semiconductor device according to claim 22,
wherein the semiconductor device is a semiconductor laser element.

25. The semiconductor device according to claim 24,
wherein the thermal degradation layer has a disordered structure.

26. The semiconductor device according to claim 22,
wherein the substrate includes a semiconductor layer which is made of InGaAIN.

27. The semiconductor device according to claim 22,
wherein the substrate includes a part which is made of SiC, sapphire and GaN.

28. The semiconductor device according to claim 22,
wherein the semiconductor device is a light-emitting diode.

29. The semiconductor device according to claim 22,
wherein the semiconductor device is a transistor or an integrated circuit thereof.
